(19) United States
(12) Patent Application Publication
(10) Pub. No.: US 2013/0167918 A1
(43) Pub. Date: Jul. 4, 2013

(54) PHOTOVOLTAIC DEVICE

(71) Applicant: Seung-Yeop MYONG, Seoul (KR)

(72) Inventor: Seung-Yeop MYONG, Seoul (KR)

(21) Appl. No.: 13/645,874

(22) Filed: Oct. 5, 2012

(30) Foreign Application Priority Data
Oct. 5, 2011 (KR) 10-2011-0101099

(51) Int. Cl. H01L 31/075

(52) U.S. Cl. 136/255

(57) ABSTRACT

Disclosed is a photovoltaic device including a first electrode including a transparent conductive oxide layer; a metal oxide layer which is placed on the first electrode; a photoelectric conversion layer which is placed on the metal oxide layer and includes a p-type semiconductor layer, an intrinsic semiconductor layer and an n-type semiconductor layer; and a second electrode which is placed on the photoelectric conversion layer.

### CROSS-REFERENCE TO RELATED APPLICATIONS

This application claims the benefit of Korean Patent Application No. 10-2011-0101099, filed Oct. 5, 2011, the entirely of which is hereby incorporated by reference.

### FIELD OF THE INVENTION

The present invention relates to a photovoltaic device.

### BACKGROUND OF THE INVENTION

Recently, as existing energy resources like oil and coal and the like are expected to be exhausted, much attention is increasingly paid to alternative energy sources which can be used in place of the existing energy sources. In the alternative energy sources, sunlight energy is abundant and has no environmental pollution. Therefore, more and more attention is paid to the sunlight energy.

A photovoltaic device, that is, a solar cell directly converts sunlight energy into electrical energy. The photovoltaic device mainly uses photovoltaic effect of semiconductor junction. In other words, when light is incident on and absorbed by a semiconductor p-i-n junction doped with p-Type impurity and n-type impurity respectively, light energy generates electrons and holes within the semiconductor and the electrons and the holes are separated from each other by an internal electric field. As a result, a photo-electro motive force is generated at both ends of the p-i-n junction. Here, if electrodes are formed at both ends of the junction and connected with wires, electric current flows externally through the electrodes and the wires.

In order that the existing energy sources such as oil is substituted with the sunlight energy source, the photovoltaic device should provide high photovoltaic conversion efficiency.

### SUMMARY OF THE INVENTION

One aspect of the present invention is a photovoltaic device. The photovoltaic device includes: a first electrode including a transparent conductive oxide layer; a metal oxide layer which is placed on the first electrode; a photoelectric conversion layer which is placed on the metal oxide layer and includes a p-type semiconductor layer, an intrinsic semiconductor layer and an n-type semiconductor layer; and a second electrode which is placed on the photoelectric conversion layer.

Another aspect of the present invention is a photovoltaic device. The photovoltaic device includes: a first electrode including a transparent conductive oxide layer; a metal oxide layer which is placed on the first electrode; a plurality of photoelectric conversion layers which are placed on the metal oxide layer and each of which includes a p-type semiconductor layer, an intrinsic semiconductor layer and an n-type semiconductor layer; and a second electrode which is placed on the photoelectric conversion layer.

### BRIEF DESCRIPTION OF THE DRAWINGS

FIG. 1 shows a photovoltaic device according to a first embodiment of the present invention;

FIG. 2 shows a multi-junction photovoltaic device according to a second embodiment of the present invention; and

FIG. 3 shows a conventional multi-junction photovoltaic device.

### DETAILED DESCRIPTION

Hereafter, an exemplary embodiment of the present invention will he described in detail with reference to the accompanying drawings. The shapes and sizes and the like of components of the drawings are exaggerated for clarity of the description. It is noted that the same reference numerals are used to denote the same elements throughout the drawings. In the following description of the present invention, the detailed description of known functions and configurations incorporated herein is omitted when it may make the subject matter of the present invention unclear.

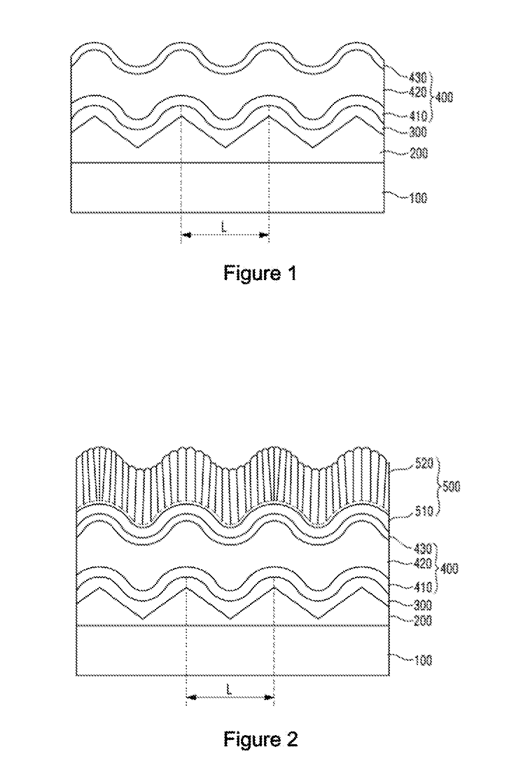

FIG. 1 shows a photovoltaic device according to a first embodiment of the present invention. As shown in FIG. 1, the photovoltaic device according to the first embodiment of the present invention may include a substrate 100, a first electrode 200, a metal oxide layer 300, a photoelectric conversion layer 400 and a second electrode (not shown).

The substrate 100 may be an insulating transparent substrate. For example, the substrate 100 may include a material such as glass. The surface of the substrate 100 is textured so that light utilization efficiency is improved by reducing light reflection and scattering the light.

The first electrode 200 placed on the substrate 100 may include a transparent conductive oxide (TCO) layer. When the TCO layer is formed on the substrate 100, the surface of the TCO layer may be textured. For example, either when ZnO is deposited by low-pressure chemical vapor deposition (LPCVD) or when SnO₂ is deposited by atmospheric pressure chemical vapor deposition (APCVD), a sharp pyramid-shaped texturing structure is, as shown in FIG. 1, formed on the surface of the TCO layer.

The texturing structure on the surface of the TCO layer scatters light incident on the substrate 100 and minimizes optical loss caused by light reflection from the surface of the TCO layer. The texturing structure also increases an optical path of a light absorber and improves light absorption of the light absorber within the photoelectric conversion layer 400. As a result, the efficiency of the photovoltaic device is enhanced.

According to the embodiment of the present invention, the metal oxide layer 300 is disposed on the textured surface of the first electrode 200. The metal oxide layer 300 has a low step-coverage and is not formed conformally on the first electrode 200. Therefore, the thickness of the metal oxide layer 300 is not uniform across the entire surface thereof. The metal oxide layer 300 is relatively thick at a V-shaped valley of the pyramid-shaped structure of the first electrode 200 and is relatively thin at the top (or projecting part) of the pyramid-shaped structure. As a result, an undulating surface having U-shaped valley may be formed on the surface of the metal oxide layer 300.

The photoelectric conversion layer 400 is disposed on the undulating surface of the metal oxide layer 300. The photoelectric conversion layer 400 includes a p-type semiconductor layer 410, an intrinsic semiconductor layer 420, i.e., a light absorber and an n-type semiconductor layer 430.

Here, since the surface of the metal oxide layer 300 is smoothly textured, the p-type semiconductor layer 410 may be formed conformally on the metal oxide layer 300. That is, the thickness of the p-type semiconductor layer 410 may be uniform across the entire surface thereof.

When the p-type semiconductor layer 410 is directly formed on the first electrode 200 having the pyramid-shaped texturing structure formed thereon, there is a problem that the thickness of the p-type semiconductor layer 410 is not uniform across the entire surface thereof. In other words, the p-type semiconductor layer 410 may be thick at the valley of the texturing structure of the first electrode 200 and may be thin at the projecting part of the texturing structure of the first electrode 200. In the thin portion of the p-type semiconductor layer, a sufficient electric field cannot be formed in the intrinsic semiconductor layer. Therefore, an open circuit voltage (Voc) becomes lower and the efficiency of the photovoltaic device may be degraded.

In order to obtain desired open circuit voltage from the photovoltaic device, it is necessary that the p-type semiconductor layer is formed to have a predetermined thickness even on the projecting part of the texturing structure of the first electrode 200. For this purpose, the p-type semiconductor layer at the valley of the texturing structure may be thicker than necessary. The large thickness of the p-type semiconductor layer may cause light absorption of the p-type semiconductor layer to be increased, so that the efficiency of the photovoltaic device may be degraded.

Therefore, as described in the embodiment of the present invention, the problem mentioned above can be avoided by placing the metal oxide layer 300 on the first electrode 200. That is, the p-type semiconductor layer 410 may be formed conformally on the metal oxide layer 300, in other words, the thickness of the p-type semiconductor layer 410 may be uniform across the entire surface thereof.

The metal oxide layer 300 may include a material having a high work function. The metal oxide layer 300 including the material having a high work function is able to contribute to the improvement of the open circuit voltage.

That is to say, the metal oxide layer 300 having high electrical conductivity is able to assist the p-type semiconductor layer 410 to form the electrical field in the intrinsic semiconductor layer 420. Therefore, the thickness of the p-type semiconductor layer 410, which is necessary for obtaining the equal open circuit voltage, can be reduced by including the metal oxide layer 300. For example, the thickness of the p-type semiconductor layer 410 may be equal to or larger than 3 nm and equal to or smaller than 10 nm. When the thickness of the p-type semiconductor layer 410 is equal to or larger than 3 nm, the sufficient electrical field can he formed in the intrinsic semiconductor layer 420. When the thickness of the p-type semiconductor layer 410 is equal to or smaller than 10 nm, undesired light absorption by the p-type semiconductor layer 410 can be prevented.

As such, since it is possible to reduce the thickness of the p-type semiconductor layer 410, which is necessary for obtaining the predetermined open circuit voltage, the amount of the light absorption by the p-type semiconductor layer 410 can be also reduced. Accordingly, the light utilization by the intrinsic semiconductor layer 420 can be enhanced. Thus, short circuit current may be increased.

Further, the metal oxide layer 300 has a visible light transmittance higher than that of the p-type semiconductor layer 410. Therefore, photovoltaic conversion efficiency can he enhanced by reducing the thickness of the p-type semiconductor layer 410.

The metal oxide layer 300 may include at least one of WO, MoO, Nb₂O₅, Sb₂O₅, PtO, IrO, AuO, PdO, RhO, NiO and CrO.

The metal oxide layer 300 may be formed by using methods such as evaporation, sputtering, e-beam vapor deposition, electrolysis, spin coating or pyrosol.

The intrinsic semiconductor layer 420 and the n-type semiconductor layer 430 are placed on the p-type semiconductor layer 410. The intrinsic semiconductor layer 420 may be formed of hydrogenated amorphous silicon or hydrogenated amorphous silicon based material. In the embodiment of the present invention, the hydrogenated amorphous silicon based material may include a non-silicon based material such as oxygen, carbon or nitrogen. For example, when the intrinsic semiconductor layer 420 includes oxygen, carbon or nitrogen, the intrinsic semiconductor layer 420 may be formed of hydrogenated amorphous silicon oxide (a-SiO:H), hydrogenated amorphous silicon carbide (a-SiC:II) or hydrogenated amorphous silicon nitride (a-SiN:H).

In the foregoing, the single-junction photovoltaic device according to the first embodiment of the present invention has been described. Hereafter, a multi-junction photovoltaic device according to a second embodiment of the present invention will be described with reference to FIG. 2. Since the descriptions of the substrate 100, the first electrode 200, the metal oxide layer 300 and the photoelectric conversion layer 400, all of which have been disclosed in the first embodiment, are also applied to the second embodiment, the same descriptions thereof will be omitted below.

FIG. 2 shows a multi-junction photovoltaic device according to a second embodiment of the present invention. The photovoltaic device according to the second embodiment of the present invention may include the substrate 100, the first electrode 200, the metal oxide layer 300, a plurality of photoelectric conversion layers 400 and 500 and a second electrode (not shown).

A first photoelectric conversion layer 400 is the same as the photoelectric conversion layer 400 described with reference to FIG. 1.

A second photoelectric conversion layer 500 is placed on the first photoelectric conversion layer 400. The second photoelectric conversion layer 500 includes a p-type semiconductor layer 510, an intrinsic semiconductor layer 520 and an n-type semiconductor layer (not shown). The first photoelectric conversion layer 400 is able to absorb more light with a short wavelength than the second photoelectric conversion layer 500. The second photoelectric conversion layer 500 is able to absorb more light with a long wavelength than the first photoelectric conversion layer 400.

The intrinsic semiconductor layer 520 included in the second photoelectric conversion layer 500 may be formed of hydrogenated micro-crystalline silicon (μc-Si:H) or hydrogenated micro-crystal line silicon based material In the embodiment of the present invention, the hydrogenated micro-crystalline silicon based material may include a non-silicon based material such as germanium. For example, when the intrinsic semiconductor layer 520 includes germanium, the intrinsic semiconductor layer 520 may be formed of hydrogenated micro-crystalline silicon germanium (μc-SiGe:H).

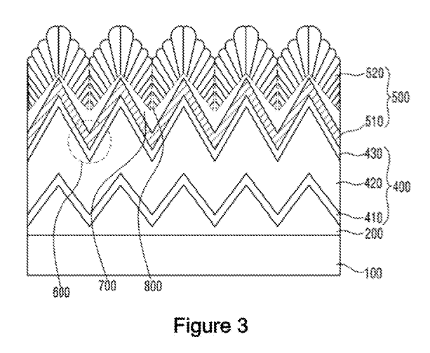

In the embodiment of the present invention, the metal oxide layer 300 is included on the surface of the first electrode 200 having the pyramid-shaped texturing structure. FIG. 3 shows that the first photoelectric conversion layer 400 and the second photoelectric conversion layer 500 have been directly formed on the first electrode 200 without including the metal oxide layer 300 on the surface of the first electrode 200 having the pyramid-shaped texturing structure.

As shown in FIG. 3, the first photoelectric conversion layer 400 including the intrinsic semiconductor layer 420 formed of hydrogenated amorphous silicon or hydrogenated amorphous silicon based material is formed on the surface of the first electrode 200 having the sharp pyramid-shaped texturing structure. Therefore, the sharp pyramid-shaped texturing structures are formed on the surfaces of the first photoelectric conversion layer 400 and the second photoelectric conversion layer 500, both of which are placed on the first electrode 200.

Here, a V-shaped valley part 600 of the texturing structure of the second photoelectric conversion layer 500 functions as a crack to prevent the hydrogenated micro crystalline silicon or the hydrogenated micro crystalline silicon based material from being formed, and also forms an amorphous incubation film 700 and a large volume of a grain boundary 800. The amorphous incubation film 700 and the grain boundary 800 function as a center of recombination of electron-hole pairs photo-created from the hydrogenated micro crystalline silicon or the hydrogenated micro crystalline silicon based material so that the open circuit voltage and fill factor of the photovoltaic device are reduced.

In the embodiment of the present invention, this problem can be solved by including the metal oxide layer 300 on the surface of the first electrode 200. That is, the multi-junction photovoltaic device shown in FIG. 2 may be formed by including the metal oxide layer 300 on the surface of the first electrode 200 having the pyramid-shaped texturing structure formed thereon.

In other words, as shown in FIG. 2, the surface of the metal oxide layer 300 is textured more smoothly than the surface of the first electrode 200. As such, the first photoelectric conversion layer 400 is formed on the undulating surface of the metal oxide layer 300. The second photoelectric conversion layer 500 is formed on the first photoelectric conversion layer 400. When the intrinsic semiconductor layer 520 including the hydrogenated micro-crystalline silicon or hydrogenated micro-crystalline silicon based material is deposited, the hydrogenated micro-crystalline silicon or hydrogenated micro-crystalline silicon based material of the second photoelectric conversion layer 500 is easily formed, so that the micro crack 600 is prevented from being formed and the incubation film 700 and a large volume of the grain boundary 800 are reduced. As a result, the characteristic of the photovoltaic device may be improved.

While FIG. 2 shows the double-junction photovoltaic device including the two photoelectric conversion layers 400 and 500, the present invention can be also applied to the multi-junction photovoltaic device including at least three photoelectric conversion layers. For example, the present invention can be also applied to a ease where, in a triple-junction photovoltaic device, the intrinsic semiconductor layer including the micro-crystalline silicon or hydrogenated micro-crystalline silicon based material is included in a bottom cell which is the farthest from a light incident side or in a middle cell.

As described above, the metal oxide layer 300 is included in the embodiment of the present invention, so that the p-type semiconductor layer may be formed to have a uniform thickness and the micro crack may be prevented from being formed in the multi-junction photovoltaic device. For this purpose, the metal oxide layer 300 may includes the following characteristics.

A ratio of a root mean square (RMS) roughness to an average pitch of the texturing structure formed on the surface of the metal oxide layer 300 formed on the first electrode 200 may be equal to or greater than 0.05 and equal to or less than 0.13. The first electrode 200 includes the TCO layer of which surface is textured to have the pyramid-shaped texturing structure. The pitch of the texturing structure is, as shown in FIGS. 1 and 2, a distance “L” between two adjacent projections. The average pitch of the texturing structure is a mean value of the pitches. After the height of the surface of the metal oxide layer 300 is measured with respect to a certain area by using an atomic force microscope (AFM), the RMS roughness is obtained through the following expression:

$$RMS roughness = \frac{1}{N} {{Q}_{i = 1}}^{N} \sqrt{{( Xi - \overline{X} )}^{2}} ,$$

where Xs is the height measured at a point “i” of the surface and \tilde{X} is an average height of the surface.

When the ratio of the RMS roughness to the average pitch is less than 0.5, the metal oxide layer 300 becomes excessively flat, and a light scattering effect may he reduced by the metal oxide layer 300. When the ratio of the RMS roughness to the average pitch is greater than 0.13, the surface becomes excessively rough, so that the crack 600 and a large volume of the grain boundary 800 may he formed or the p-type semiconductor layer may not be formed conformally on the metal oxide layer 300.

The pitch of the texturing structure is an indicator for the wavelength of light which can be scattered and cannot be an indicator for flatness. Therefore, in the present invention, the ratio of the RMS roughness to the average pitch of the texturing structure of the metal oxide layer 300 surface is maintained equal to or greater than 0.05 and equal to or less than 0.13. As a result, the light scattering can be appropriately maintained and the p-type semiconductor layer is conformally formed, and the formation of the micro crack can be prevented from being generated.

The thickness of the metal oxide layer 300 may be equal to or larger than 10 nm and equal to smaller than 300 nm. When the thickness of the metal oxide layer 300 is equal to or larger than 10 nm, the surface unevenness of the first electrode 200 is sufficiently alleviated, so that the p-type semiconductor layer may be uniformly formed and the crack formation may be prevented. When the thickness of the metal oxide layer 300 is equal to or smaller than 300 nm, it is possible to prevent the light absorption by the metal oxide layer 300 from excessively increasing and to prevent manufacturing time and manufacturing cost from increasing.

According to the embodiment of the present invention, the metal oxide layer 300 is placed on the first electrode 200 including the TCO layer having the pyramid-shaped texturing structure formed thereon, so that the p-type semiconductor layer may be uniformly formed on the first electrode 200 and the thickness of the p-type semiconductor layer may be reduced. As a result, the open circuit voltage and the photovoltaic conversion efficiency of the photovoltaic device can be improved.

According to the embodiment of the present invention, the metal oxide layer 300 is placed on the first electrode 200 including the TCO layer having the pyramid-shaped texturing structure formed thereon. Therefore, when the intrinsic semiconductor layer including the micro-crystalline silicon or hydrogenated micro-crystalline silicon based material is formed, it is possible to prevent the micro crack or a large volume of the grain boundary from being formed. As a result, the fill factor of the photovoltaic device can he enhanced.

While the embodiment of the present invention has been described with reference to the accompanying drawings, it can be understood by those skilled in the art that the present invention can be embodied in other specific forms without departing from its spirit or essential characteristics. Therefore, the foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

What is claimed is:

1. A photovoltaic device comprising:
a first electrode including a transparent conductive oxide layer;
a metal oxide layer which is placed on the first electrode;
a photoelectric conversion layer which is placed on the metal oxide layer and includes a p-type semiconductor layer, an intrinsic semiconductor layer and an n-type semiconductor layer; and
a second electrode which is placed on the photoelectric conversion layer.

2. A photovoltaic device comprising:
a first electrode including a transparent conductive oxide layer;
a metal oxide layer which is placed on the first electrode;
a plurality of photoelectric conversion layers which are placed on the metal oxide layer and each of which includes a p-type semiconductor layer, an intrinsic semiconductor layer and an n-type semiconductor layer; and
a second electrode which is placed on the photoelectric conversion layer.

3. The photovoltaic device of claim 1, wherein the metal oxide layer comprises at least one of WO, MoO, Nb₂O₅, Sb₂O₅, PtO, IrO, AuO, PdO, RhO, NiO and CrO.

4. The photovoltaic device of claim 1, wherein a thickness of the metal oxide layer is equal to or larger than 10 nm and equal to smaller than 300 nm.

5. The photovoltaic device of claim 1, wherein a ratio of a root mean square roughness to an average pitch of a texturing structure of the surface of the metal oxide layer is equal to or greater than 0.05 and equal to or less than 0.13.

6. The photovoltaic device of claim 1, wherein a thickness of the p-type semiconductor layer contacting with the metal oxide layer is equal to or larger than 3 nm and equal to or smaller than 10 nm.

7. The photovoltaic device of claim 1, wherein the intrinsic semiconductor layer of the photoelectric conversion layer contacting with the metal oxide layer comprises hydrogenated amorphous silicon or hydrogenated amorphous silicon based material.

8. The photovoltaic device of claim 2, wherein the intrinsic semiconductor layer of at least one of the plurality of the photoelectric conversion layers comprises hydrogenated micro-crystalline silicon or hydrogenated micro-crystalline silicon based material.

9. The photovoltaic device of claim 2, wherein the metal oxide layer comprises at least one of WO, MoO, Nb₂O₅, Sb₂O₅, PtO, IrO, AuO, PdO, RhO, NiO and CrO.

10. The photovoltaic device of claim 2, wherein a thickness of the metal oxide layer is equal to or larger than 10 nm and equal to smaller than 300 nm.

11. The photovoltaic device of claim 2, wherein a ratio of a root mean square roughness to an average pitch of a texturing structure of the surface of the metal oxide layer is equal to or greater than 0.05 and equal to or less than 0.13.

12. The photovoltaic device of claim 2, wherein a thickness of the p-type semiconductor layer contacting with the metal oxide layer is equal to or larger than 3 nm and equal to or smaller than 10 nm.

13. The photovoltaic device of claim 2, wherein the intrinsic semiconductor layer of the photoelectric conversion layer contacting with the metal oxide layer comprises hydrogenated amorphous silicon or hydrogenated amorphous silicon based material.
